(19) United States
(12) Patent Application Publication
(10) Pub. No.: US 2026/0090307 A1
(43) Pub. Date: Mar. 26, 2026

(54) METHOD FOR THINNING A COMPOSITE STRUCTURE CARRIED BY A POLYCRYSTALLINE SIC CARRIER SUBSTRATE, WITH REDUCED WARPAGE

(71) Applicant: Soitec, BERNIN (FR)

(72) Inventors: Walter Schwarzenbach, BERNIN (FR); Séverin Rouchier, BERNIN (FR); Sylvain Monnoye, Le Bourget-du-Lac (FR)

(21) Appl. No.: 19/109,874

(22) PCT Filed: Sep. 6, 2023
(86) PCT No.: PCT/FR2023/051341

§ 371 Date: Mar. 7, 2025

(30) Foreign Application Priority Data
Sep. 7, 2022 (FR) FR2208960

(51) Int. Cl. H10P 52/40; H10P 14/20; H10P 58/00

(52) U.S. Cl. CPC H10P 52/402; H10P 14/2904; H10P 14/2924; H10P 14/3408; H10P 14/3458; H10P 58/00

(57) ABSTRACT

A method of processing a composite structure including a thin layer of single-crystal silicon carbide disposed on a polycrystalline silicon carbide carrier substrate, includes, after formation of electronic component elements on a front face of the composite structure, grinding a rear face of the composite structure and removing a work-hardened layer present on the surface of the rear face as a result of the grinding process.

### CROSS-REFERENCE TO RELATED APPLICATIONS

This application is a national phase entry under 35 U.S. C. § 371 of International Patent Application PCT/FR2023/051341, filed Sep. 6, 2023, designating the United States of America and published as International Patent Publication WO 2024/052619 A1 on Mar. 14, 2024, which claims the benefit under Article 8 of the Patent Cooperation Treaty of French Patent Application Serial No. FR2208960, filed Sep. 7, 2022.

### TECHNICAL FIELD

The field of the present disclosure is that of processing a composite structure bearing elements of electronic components produced on a single-crystal silicon-carbide layer placed on a polycrystalline silicon-carbide carrier substrate.

### BACKGROUND

Silicon carbide (SiC) is increasingly widely used in power electronics applications, in particular, to meet the needs of new fields of application of electronics, such as, for example, electric vehicles. Specifically, power devices and integrated power-supply systems based on single-crystal SiC are able to handle a much higher power density than their conventional silicon counterparts, and to do so with active regions of smaller size.

Nevertheless, substrates made of single-crystal SiC intended for the microelectronics industry remain expensive and difficult to supply in large sizes. It is therefore advantageous to employ solutions that result in production of composite structures typically comprising a thin layer made of single-crystal SiC on a lower cost carrier substrate. One such solution is the SMART CUT™ process, which makes it possible, for example, to manufacture a composite structure comprising a thin layer made of single-crystal SiC (which is sampled from a donor substrate made of single-crystal SiC) making direct contact with a carrier substrate made of polycrystalline SiC. The composite structure has a front side on the side of the thin layer of single-crystal SiC and a back side on the side opposite the front side.

During front-end processing, elements of electronic components (for example, elements allowing vertical transistors to be formed) are formed on the front side of the composite structure via a combination of steps of semiconductor-film deposition or epitaxial growth, of lithography, of etching, of doping, of metal deposition and of passivation. The back side of the composite structure is then thinned by grinding, which, by way of example for a carrier substrate of 150 mm diameter, reduces its thickness from 350 μm to 180 μm, or even to 100 μm. The reduced thickness targeted by this thinning depends on the back-end processing that will subsequently be carried out, and in which the chips are diced and encapsulated (packaged). This thickness is a compromise between the physical properties of the material (need to support the chips mechanically) and its electrical performance (thinning decreases the contribution of the polycrystalline SiC carrier substrate to electrical losses).

The grinding causes the composite structure to warp. This warp remains of limited amplitude after grinding of the back side of a single-crystal SiC carrier substrate, for example, on the order of 400 to 600 μm for a carrier substrate of 150 mm diameter. In contrast, this warp has a large amplitude after grinding of the same type of the back side of a polycrystalline SiC carrier substrate, for example, close to 1000 μm for a carrier substrate of 150 mm diameter. This large amplitude may exceed an acceptable level of warp, for example, on the order of 600 μm, allowing after thinning the composite structure to be handled by the equipment used during back-end processing operations.

### BRIEF SUMMARY

The objective of the present disclosure is to provide a solution making it possible to thin the back side of a composite structure comprising a thin layer of single-crystal SiC on which elements of electronic components have been produced and which is borne by a polycrystalline SiC carrier substrate, while limiting warp to a level acceptable for the subsequent back-end processing.

To this end, the present disclosure provides a process for processing a composite structure comprising a thin layer of single-crystal silicon carbide placed on a polycrystalline silicon-carbide carrier substrate. The composite structure has a front side on the side of the thin layer of single-crystal silicon carbide and a back side opposite the front side. The process comprises, after forming elements of electronic components on the front side of the composite structure, thinning the composite structure from its back side by grinding the polycrystalline silicon-carbide carrier substrate and removing a work-hardened layer present on the surface of the back side after grinding.

Some preferred but non-limiting aspects of this process are as follows:
the polycrystalline silicon-carbide carrier substrate has, before the thinning, a thickness greater than 300 μm and, after the thinning, a thickness less than 200 μm, and preferably a thickness between 100 μm and 200 μm;
the grinding of the back side comprises, in succession, coarse grinding and fine grinding;
the coarse grinding is carried out with a grinding wheel, a size of the abrasive grit of which is characterized by a mesh of less than 5000;
the fine grinding is carried out with a grinding wheel, a size of the abrasive grit of which is characterized by a mesh of greater than 5000;
the fine grinding is carried out in such a way as to remove material of a thickness between 1 μm and 3 μm;
the coarse grinding is carried out in such a way as to remove material of a thickness greater than 100 μm;
the work-hardened layer is removed by polishing the back side;
the polishing is mechanical polishing or chemical-mechanical polishing;
the polishing is carried out for between 5 and 30 minutes;
the polishing is carried out so as to remove a thickness of material of between 0.2 μm and 2 μm;
it further comprises a metallization of the back side following removal of the work-hardened layer;
following the metallization, the composite structure is subjected to final fabrication operations including chip dicing.

### BRIEF DESCRIPTION OF THE DRAWINGS

Other aspects, aims, advantages and features of the present disclosure will become more clearly apparent on reading the following detailed description of preferred embodiments thereof, which description is given by way of non-limiting example, with reference to the appended drawings, in which:

FIG. 1 is a schematic cross-sectional view of a single-crystal SiC donor substrate;

FIG. 2 is a schematic cross-sectional view of formation, by implantation of ionic species, of a weakened plane in the donor substrate of FIG. 1, with a view to defining a thin layer of single-crystal SiC to be transferred;

FIG. 3 is a schematic cross-sectional view of bonding of the donor substrate of FIG. 2 and of a polycrystalline SiC carrier substrate;

FIG. 4 is a schematic cross-sectional view of detachment of the donor substrate along the weakened plane with a view to transferring the thin single-crystal SiC layer to the polycrystalline SiC carrier substrate and thus forming a composite structure;

FIG. 5 is a schematic cross-sectional view of formation of elements of electronic components on the front side of the composite structure of FIG. 4;

FIG. 6 is a schematic cross-sectional view of thinning of the back side of the composite structure of FIG. 5;

FIG. 7 is a schematic cross-sectional view of removal of the work-hardened layer present on the surface of the back side after thinning; and

FIG. 8 is a graph illustrating warp measurements in various steps of a processing process post-fabrication of elements of electronic components.

### DETAILED DESCRIPTION

The present disclosure relates to a process for processing a composite structure comprising a thin layer of single-crystal SiC placed on a polycrystalline SiC carrier substrate and elements of electronic components formed on the thin layer of single-crystal SiC.

This processing may have been preceded by transfer, in accordance with the SMART CUT™ process, of the thin layer of single-crystal SiC to the carrier substrate from a donor substrate, at least a surface portion of which is made of single-crystal SiC.

The donor substrate may be a bulk substrate of single-crystal SiC. In other embodiments, the donor substrate may be a composite substrate, comprising a surface layer of single-crystal SiC and at least one other layer of another material. In this case, the layer of single-crystal SiC preferably has a thickness greater than or equal to 0.3 μm.

The polycrystalline SiC carrier substrate is typically produced by chemical vapor deposition of polycrystalline SiC on a growth substrate, a graphite substrate, for example. The carrier substrate thus has columnar grains oriented in the growth direction of the deposition. The polycrystalline SiC carrier substrate preferably has an initial thickness greater than 300 μm. For example, the polycrystalline SiC carrier substrate may take the form of a wafer of 150 mm diameter having an initial thickness of 350+/−25 μm. Alternatively, the polycrystalline SiC carrier substrate may take the form of a wafer of 200 mm diameter having an initial thickness of about 500 μm.

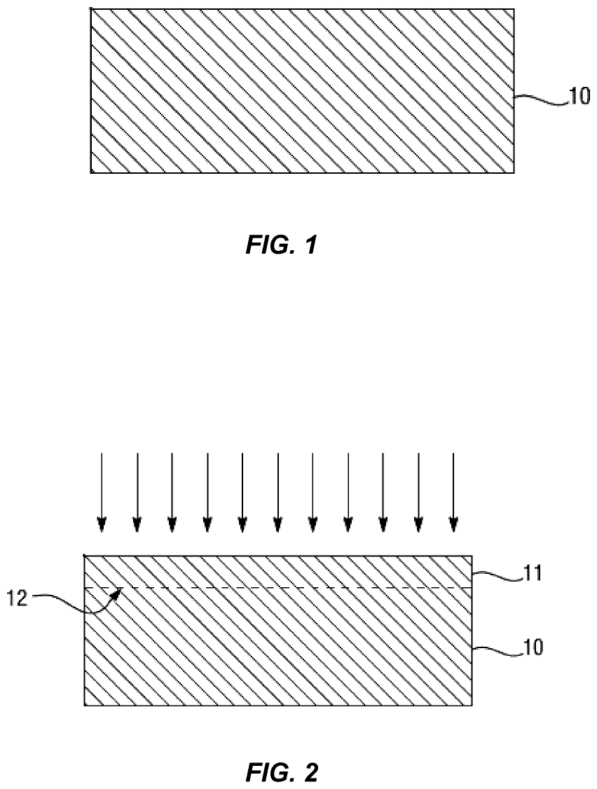

With reference to FIG. 1, the transfer in accordance with the SMART CUT™ process begins with provision of a donor substrate 10, at least a surface portion of which is made of single-crystal SiC. In the figures, a bulk substrate 10 of single-crystal SiC has been shown.

With reference to FIG. 2, the transfer further comprises implantation of ionic species into the donor substrate 10 so as to form a weakened plane 12 defining a thin layer 11 of single-crystal SiC to be transferred. The implanted species typically comprise hydrogen and/or helium. A person skilled in the art will be able to define the required implantation dose and energy.

When the donor substrate is a composite substrate, the implantation is carried out so as to form the weakened plane in the surface layer of single-crystal SiC of the donor substrate.

Preferably, the thin layer 11 of single-crystal SiC has a thickness less than 1 μm. Specifically, such a thickness is accessible on an industrial scale with the SMART CUT™ process. In particular, implanting devices available on industrial fabrication lines allow such an implantation depth to be obtained.

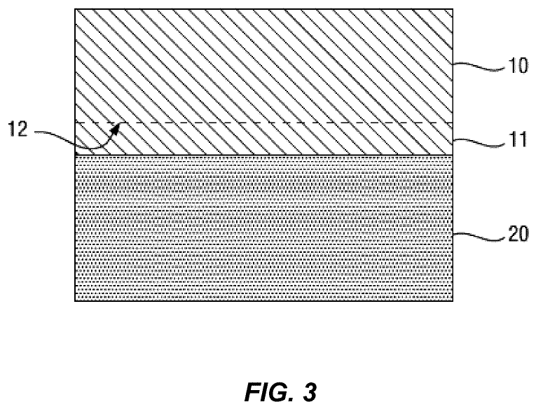

With reference to FIG. 3, the transfer comprises, after the implantation, bonding the donor substrate and carrier substrate 20, the thin layer 11 of single-crystal SiC being at the interface. The bonding may be atomic diffusion bonding (ADB).

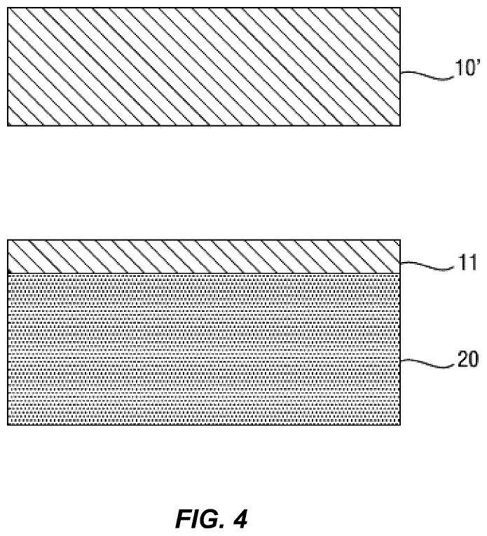

With reference to FIG. 4, the transfer then comprises detachment of the donor substrate 10 along the weakened plane 12 so as to transfer the thin layer 11 of single-crystal SiC to the carrier substrate 20. In a known manner, this detachment can be caused by a heat treatment, a mechanical action or a combination of these means. The remainder 10′ of the donor substrate may optionally be recycled with a view to another use.

One or more finishing operations may then be applied to the transferred layer 11 of single-crystal SiC. It is, for example, possible to carry out smoothing, cleaning or even polishing, chemical-mechanical polishing (CMP), for example, to remove defects related to the implantation of ionic species and to reduce the roughness of the transferred layer 11 of single-crystal SiC. A high-temperature heat treatment may also be carried out, which has the effect of stabilizing the structure and thus of guaranteeing its geometry in the following steps, provided that surface elements of electrical transistor components have not been deposited on the surface.

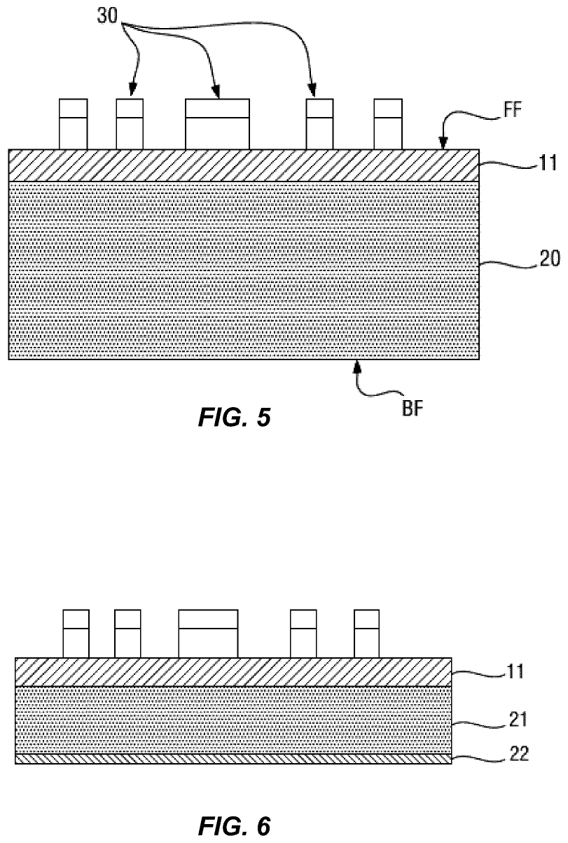

As shown in FIG. 5, elements 30 of electronic components are then formed on the thin layer 11 of single-crystal SiC, typically via a combination of steps of semiconductor-film deposition or epitaxial growth, of lithography, of etching, of doping, of metal deposition and of passivation. These elements 30 of electronic components, for example, comprise elements of vertical transistors. These elements 30 are placed on a front side FF of the composite structure, which is on the side of the thin layer 11 of single-crystal SiC. The composite structure moreover has a back side BF opposite the front side FF.

Once these elements 30 of electronic components have been formed on the front side FF, the composite structure is processed. This processing comprises thinning the composite structure from its back side BF to decrease its thickness to a target thickness compliant with the requirements of the back-end processing. This target thickness is, for example, 180 μm, or even less.

As shown in FIG. 6, this processing comprises grinding the back side BF of the composite structure, i.e., grinding the free side of the polycrystalline SiC carrier substrate 20. The front side FF is, for its part, typically covered with a protective tape. After grinding the back side of the composite structure, the thinned composite structure has a thickness preferably between 100 μm and 200 μm. Alternatively, the thinned composite structure may have a thickness less than 100 μm if precautions are taken to ensure the mechanical stability of the wafer after thinning. As indicated above, this grinding generates warp that may be more than twice as great as that observed when identical grinding is applied to the back side of a single-crystal SiC carrier substrate bearing elements of similar electronic components on the front side.

This substantial warp could be due:
to employment of the SMART CUT™ process, which associates a thin layer of single-crystal SiC and a polycrystalline SiC carrier substrate, namely materials that have slightly different coefficients of thermal expansion and the bonding interface of which may therefore exhibit a residual stress capable of causing sensitivity to warp;
to a contribution of the bulk carrier substrate that, because of its fabrication process, involves chemical vapor deposition followed by an anneal, may retain a residual stress;
to a contribution of the surface of the carrier substrate that, under the effect of grinding, ends up with a specific surface roughness or a damaged surface region leading to a surface stress being induced.

According to the present disclosure, the grinding of the back side of the composite structure may comprise coarse grinding followed by fine grinding.

The coarse grinding allows a significant thickness of material, greater than 100 um of polycrystalline SiC, to be removed at a rate compatible with an industrial process. For example, the coarse grinding may remove a thickness of polycrystalline SiC of between 150 μm and 250 μm for a substrate of 150 mm diameter, and a thickness of polycrystalline SiC of between 300 μm and 400 μm for a substrate of 200 mm diameter. The coarse grinding may remove material at a rate greater than 0.2 μm/min, for example, at a rate of 0.3 μm/min. It may be carried out by way of a grinding wheel a size of the abrasive grit of which is characterized by a mesh of less than 5000, for example, a mesh of 2000.

The coarse grinding is likely to generate a significant surface stress on the polycrystalline SiC, leading to substantial warp. In particular, the coarse grinding generates crystal defects to a depth of a few microns in the columnar microstructure of the polycrystalline SiC and leads to formation of a work-hardened layer on the surface of the back side of the carrier substrate.

The fine grinding allows the stress created beforehand to be reduced by removing, for example, between 1 and 3 μm of material. It may be carried out by way of a grinding wheel, a size of the abrasive grit of which is characterized by a mesh greater than 5000, for example, a mesh of 8000. The fine grinding is carried out at a slower rate than the coarse grinding, preferably at a rate less than 0.2 μm/min. At the end of the fine grinding, the warp is considerably reduced but remains greater than the acceptable warp level for implementation of the back-end processing. The fine grinding thus reduces the thickness of the work-hardened layer, without completely eliminating it.

According to one particular embodiment of the coarse grinding, the coarse grinding may itself successively comprise very coarse grinding and less coarse grinding. The very coarse grinding may be carried out by way of a grinding wheel, a size of the abrasive grit of which is characterized by a mesh of less than 1000, for example, a mesh of 300, and the less coarse grinding may be carried out by way of a grinding wheel, the size of the grit of which is characterized by a mesh of less than 5000, for example, a mesh of 2000. The very coarse grinding is preferably carried out at a rate greater than the rate of the less coarse grinding. In this embodiment of the coarse grinding, the very coarse grinding removes most of the total thickness of the polycrystalline SiC removed by coarse grinding, and the less coarse grinding removes the last few microns. For example, the less coarse grinding removes 20 μm of the total thickness of polycrystalline SiC removed by coarse grinding. Specifically, the very coarse grinding allows the total length of the grinding process to be shortened but generates a very thick work-hardened layer on the surface of the back side of the carrier substrate, of about 20 μm thickness. The less coarse grinding allows the very thick work-hardened layer to be removed. The less coarse grinding also generates a work-hardened layer, but the thickness of the work-hardened layer generated by the less coarse grinding is on the order of a few microns, as mentioned above.

In the embodiment in which the coarse grinding successively comprises very coarse grinding and less coarse grinding, the coarse grinding is also followed by fine grinding as described above. The less coarse grinding makes it possible to obtain a work-hardened layer that is less thick than the very thick work-hardened layer generated by the very coarse grinding, which can be thinned by fine grinding, then finally removed in a time compatible with an industrial process. As shown in FIG. 6, the composite structure thus has, following its thinning from the back side by grinding, a work-hardened layer 22 on the surface of the thinned polycrystalline SiC substrate 21, this work-hardened layer 22 not having been completely removed by the fine grinding.

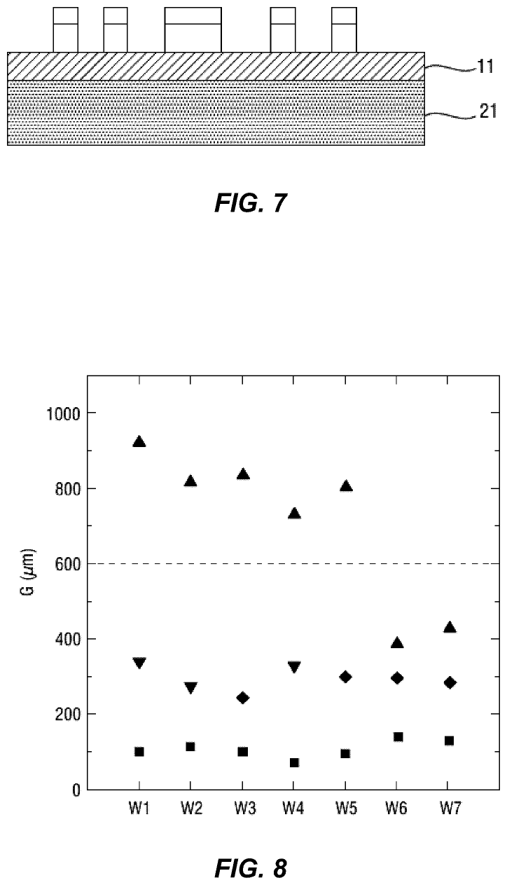

According to the present disclosure, and with reference to FIG. 7, the work-hardened layer 22 present on the surface of the back side of the composite structure after thinning is then removed. This removal is, for example, achieved by polishing the thinned back side. This polishing may be carried out so as to remove a thickness of less than 3 μm, for example, a thickness of less than 2 μm, or even a thickness of between 0.2 μm and 1 μm, or preferably of between 0.2 μm and 0.5 μm. This polishing has the advantage, in addition to reducing surface roughness, of reducing warp to an acceptable level for implementation of the back-end processing.

The polishing may be carried out for between 5 and 30 minutes, for 10 minutes, for example. It may be carried out at a pressure between 5 and 100 decaN, and preferably between 7 decaN and 30 decaN. The polishing may be mechanical polishing (simple mechanical action, with no chemical action) or chemical-mechanical polishing (CMP).

Following removal of the work-hardened layer, the process comprises a step of metallization, for example, localized metallization, of the back side of the composite structure. This metallization aims to form contacts or electrodes (for example, vertical-transistor drains) on the back side for the elements of electronic components formed on the front side. In this context, it is preferable to have previously removed the work-hardened layer by mechanical polishing. Specifically, unlike chemical-mechanical or purely chemical polishing, mechanical polishing has the advantage of avoiding the creation of additional roughness as a result of decoration of grain boundaries and, hence, leads to a surface finish that is more favorable to adhesion of the metallization.

Once this metallization has been carried out, the composite structure processed according to the present disclosure, which has a far lower warp, may undergo the final fabrication operations of back-end processing, and, in particular, chip dicing.

FIG. 8 shows measurements of warp G (in μm) of five composite structures W1-W5, each consisting of a thin layer of single-crystal SiC on a carrier substrate made of polycrystalline SiC and bearing elements of electronic components on their front side, and two bulk substrates W6-W7 of single-crystal SiC bearing identical elements of electronic components on their front side. More precisely, in FIG. 8, the squares represent the warp before thinning from the back side, the upwards-pointing triangles represent the warp after thinning from the back side comprising in succession coarse grinding and fine grinding, the downwards-pointing triangles represent the warp after removal of the work-hardened layer by mechanical polishing and the diamonds represent the warp after removal of the work-hardened layer by chemical-mechanical polishing.

It may be seen that the warp of the bulk single-crystal SiC substrates W6-W7 is already acceptable after thinning, whereas the warp of the composite structures W1-W5 is substantial after thinning, greater than the maximum acceptable value of 600 μm. However, it may be seen that after removal of the work-hardened layer, the warp of the composite structures W1-W5 is clearly reduced and is then less than the acceptable limiting value of 600 μm.

1. A method of processing a composite structure including a thin layer of single-crystal silicon carbide disposed on a polycrystalline silicon carbide carrier substrate, the composite structure having a front side on a side of the thin layer of single-crystal silicon carbide and a back side opposite the front side, the method comprising, after forming elements of electronic components on the front side of the composite structure, thinning the composite structure from the back side by grinding the polycrystalline silicon carbide carrier substrate and removing a work-hardened layer present on the surface of the back side after grinding.

2. The method of claim 1, wherein the polycrystalline silicon-carbide carrier substrate has, before the thinning, a thickness greater than 300 μm and, after the thinning, a thickness less than 200 μm.

3. The method of claim 2, wherein the grinding of the back side comprises, in succession, coarse grinding and fine grinding.

4. The method of claim 3, wherein the coarse grinding is carried out with a grinding wheel, a size of abrasive grit of which is characterized by a mesh of less than 5000.

5. The method of claim 4, wherein the fine grinding is carried out with a grinding wheel, a size of abrasive grit of which is characterized by a mesh of greater than 5000.

6. The method of claim 5, wherein the fine grinding is carried out in such a way as to remove material of a thickness between 1 μm and 3 μm.

7. The method of claim 6, wherein the coarse grinding is carried out in such a way as to remove material of a thickness greater than 100 μm.

8. The method of claim 1, wherein the work-hardened layer is removed by polishing the back side.

9. The method of claim 8, wherein the polishing is mechanical polishing.

10. &The method of claim 8, wherein the polishing is chemical-mechanical polishing.

11. The method of claim 8, wherein the polishing is carried out for between 5 and 30 minutes.

12. The method of claim 8, wherein the polishing is carried out so as to remove a thickness of material of less than 3 μm.

13. The method of claim 1, further comprising a metallization of the back side following removal of the work-hardened layer.

14. The method of claim 13, wherein, following the metallization, the composite structure is subjected to final fabrication operations including chip dicing.

15. The method of claim 2, wherein the polycrystalline silicon-carbide carrier substrate has, after the thinning, a thickness between 100 μm and 200 μm.

16. The method of claim 1, wherein the grinding of the back side comprises, in succession, coarse grinding and fine grinding.

17. The method of claim 16, wherein the coarse grinding is carried out with a grinding wheel, a size of abrasive grit of which is characterized by a mesh of less than 5000.

18. The method of claim 16, wherein the fine grinding is carried out with a grinding wheel, a size of abrasive grit of which is characterized by a mesh of greater than 5000.

19. The method of claim 16, wherein the fine grinding is carried out in such a way as to remove material of a thickness between 1 μm and 3 μm.

20. The method of claim 16, wherein the coarse grinding is carried out in such a way as to remove material of a thickness greater than 100 μm.
